(19) United States
(12) Patent Application Publication
(10) Pub. No.: US 2017/0328793 A1
(43) Pub. Date: Nov. 16, 2017

(54) A SENSING DEVICE, SYSTEM AND A METHOD OF MANUFACTURE THEREOF

(71) Applicants: SINGAPORE HEALTH SERVICES PTE LTD, SINGAPORE (SG); AGENCY FOR SCIENCE, TECHNOLOGY AND RESEARCH, SINGAPORE (SG); ALEXANDRA HEALTH PTE LTD, SINGAPORE (SG)

(72) Inventors: HWAN ING HEE, SINGAPORE (SG); TAO SUN, SINGAPORE (SG); NING XUE, SINGAPORE (SG); ALEX YUANDONG GU, SINGAPORE (SG); HONGBIN YU, SINGAPORE (SG); YVONNE WONG, SINGAPORE (SG)

(73) Assignees: SINGAPORE HEALTH SERVICES PTE LTD, SINGAPORE (SG); AGENCY FOR SCIENCE, TECHNOLOGY AND RESEARCH, SINGAPORE (SG); ALEXANDRA HEALTH PTE LTD, SINGAPORE (SG)

(21) Appl. No.: 15/528,052

(22) PCT Filed: Nov. 19, 2015
(86) PCT No.: PCT/SG2015/050465

§ 371 Date: May 18, 2017

(30) Foreign Application Priority Data
Nov. 19, 2014 (SG) 10201407884Y

(51) Int. Cl. G01L 1/14; G01D 5/24; B81B 3/00

(52) U.S. Cl. CPC G01L 1/14; B81B 3/0027; G01D 5/2405

(57) ABSTRACT

A sensing device comprising a first array of electrodes encapsulated in a first elastomeric layer; a second array of electrodes encapsulated in a second elastomeric layer; a third elastomeric layer intermediate the first and second elastomeric layer and comprising an array of micro-structures, wherein said electrodes and elastomeric layers are configured such that a displacement of said micro-structures, in response to one or more forces and/or pressures applied to said device, causes a capacitance of said device to vary as a function of said forces and/or pressure applied.

### FIELD OF THE INVENTION

The present invention relates to a sensing device, a sensing system incorporating one or more sensing devices, and a method of manufacturing such a sensing device. In particular, the invention relates to a sensing device that can be used to monitor forces or pressure exerted on an object, such as but not limited to an area of a human body.

### BACKGROUND

Any listing or discussion of a prior-published document in this specification should not necessarily be taken as an acknowledgement that the document is part of the state of the art or is common general knowledge.

Force sensing devices have various applications including in healthcare and medicine (biomedical implants, biosensors, biomedical interface pressure transducer, force/pressure monitoring during medical/surgical procedures, weight bearing monitors and so on). In recent years, forces sensing resistors and piezo-resistive force sensors have been devised for use in the area of healthcare and medicine (e.g. to guide the delivery of cricoid pressure). These sensing devices suffer from many deficiencies, such as high cost of production, unknown and/or low measurement accuracy, limited sensitivity, large device/system footprint, and long response time.

Accordingly, there remains a challenge to design and manufacture a cost-effective, and compact sensing device with improved sensitivity, and which can allow real-time and accurate measurements of the forces exerted on an object.

### SUMMARY OF THE INVENTION

In accordance with a first aspect of the invention there is provided a sensing device comprising a first array of electrodes encapsulated in a first elastomeric layer; a second array of electrodes encapsulated in a second elastomeric layer; a third elastomeric layer intermediate the first and second elastomeric layer and comprising an array of micro-structures, wherein said electrodes and elastomeric layers are configured such that a displacement of said micro-structures, in response to one or more forces and/or pressures applied to said device, causes a capacitance of said device to vary as a function of said forces and/or pressure applied.

In a second aspect, the invention provides a sensing system comprising a display unit; a power supply; one or more sensing devices according to an aspect of the invention; and a printed circuit board comprising one or more integrated circuits configured to receive one or more signals from said sensing devices, and to process said signals received to information for real-time display on the display unit.

In a third aspect, the invention provides a method of fabricating a sensing device comprising the steps of providing a first layer of electrodes encapsulated in a first elastomeric layer; providing a second layer of electrodes encapsulated in a second elastomeric layer; providing a third layer elastomeric layer comprising an array of micro-structures; arranging said layers such that the third layer is intermediate the first and second layers, and a displacement of said micro-structures, in response to one or more forces and/or pressures applied to said device, causes a capacitance of said device to vary as a function of the forces and/or pressures applied.

### BRIEF DESCRIPTION OF THE DRAWINGS

It will be convenient to further describe the present invention with respect to the accompanying drawings that illustrate possible arrangements of the invention. Other arrangements of the invention are also possible and consequently, the particularity of the accompanying drawings is not to be understood as superseding the generality of the preceding description of the invention.

FIG. 1 is a cross-section of a sensing device according to one embodiment of the present invention;

FIG. 2 is a side perspective view of a set-up for a sensing system incorporating a sensing device according to an embodiment of the present invention;

FIG. 3 shows an enlarged figure of the sensing device in FIG. 2;

FIG. 4 shows a schematic diagram of the sensing system in FIGS. 2 and 3; and

FIG. 5 shows a sensing system according to an embodiment of the present invention for a specific application.

### DETAILED DESCRIPTION OF CERTAIN EMBODIMENTS

Example embodiments of the invention will now be described more fully hereinafter with reference to the accompanying drawings; however, the invention may be embodied in different forms and should not be constructed as limited to the embodiments set forth herein. Rather, these embodiments are provided so that this disclosure will be thorough and complete, and will fully convey exemplary implementations to those skilled in the art.

As used herein, the terms/sentences “micro-structured elastomeric layer”, structured elastomeric layer” and “elastomeric layer comprising micro-structures” shall be used interchangeably.

As used herein, the terms “biocompatible” or “biocompatibility” used in the context of a substance/object shall be interpreted as one that does not generally cause significant adverse reactions (e.g. toxic or antigenic responses) to cells, tissues, organs or the organisms as a whole, for example, whether it is in contact with the cells, tissues, organs or localized within the organism, whether it degrades within the organism, remains for extended periods of time, or is excreted whole. A “biocompatible” elastomer may be selectively compatible in that it exhibits biocompatibility with certain cells, tissues, organs or even certain organisms. For example, the “biocompatible” elastomer may be selectively biocompatible with vertebrate cells, tissues and organs but toxic to cells from pathogens or pathogenic organisms. In some circumstances, the “biocompatible” elastomer may also be toxic to cells derived from tumours and/or cancer.

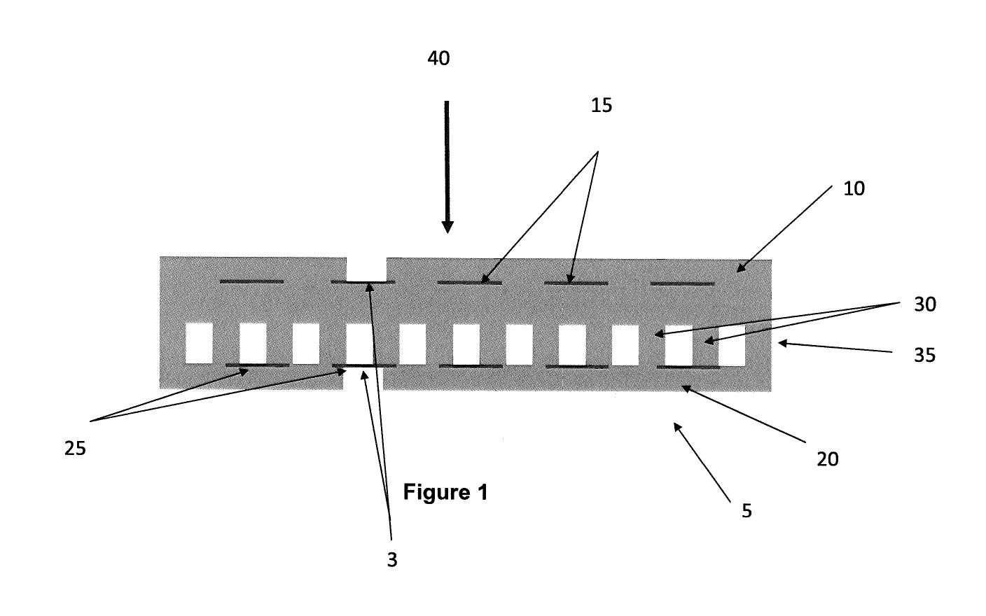

FIG. 1 shows a cross-section of a sensing device 5 according to an embodiment of the present invention. The sensing device 5 comprises a first elastomeric layer 10, a second elastomeric layer 20, and a third elastomeric layer 35 intermediate the first 10 and second 20 elastomeric layer. The third elastomeric layer 35 may comprise an array of micro-structures 30. Further, the sensing device may be provided with a first array of electrodes 15 encapsulated in the first elastomeric layer 10, and a second array of electrodes 25 encapsulated in the second elastomeric layer 20.

Bonding pads 3 may be provided to expose the array of electrodes 15, 25 for connection with communication devices such as cables. Such a connection permits the transmission of electrical signals between the electrodes, and one or more devices (e.g. printed circuit board). The bonding pads also serve to provide electrical connection to the sensing device 5.

Accordingly, the micro-structures comprise a plurality of voids, and so provide room for the micro-structures to deform/displace elastically when one or more external forces/pressure 40 are applied to the sensing device 5. Relative to an unstructured elastomeric layer with no structures/micro-structures, a micro-structured/structured elastomeric layer may be displaced/deformed more easily, and exhibits a shorter (in the range of milliseconds; see Example 4) stress relaxation time (the gradual disappearance of stresses after it has been deformed/displaced), and smaller elastic resistance (the micro-structured layer is more elastic compared to an unstructured layer). This in turn leads to shorter response time and higher sensitivity to the external forces/pressures applied to the sensing device.

Specifically, the micro-structures would occupy the area defined between the voids when external forces are applied. This in turn brings the first and second arrays of electrodes 15 and 25 closer to each other, reducing the distance between the arrays of electrodes. Based on the expression below, the capacitance between the electrodes (hence the sensing device) is inversely proportional to the separation distance between the electrodes, and so, a reduction in distance between the electrodes would lead to an increase in capacitance.

C=(∈ᵣ∈ₒ)(n−1)A/d

where,
C is the capacitance in Farads (F);
∈ᵣ is the dielectric constant of the material between the electrodes (F/m);
∈Cₒ is the dielectric constant of free space (F/m);
d is the separation distance between the electrodes in meters (m); and
A (n−1) the total resultant area of a set of electrodes in square meters (m²) where n is the number of parallel electrodes.

Further, it has been reported that the dielectric constant of the micro-structured elastomeric layer is 2.34 (i.e. micro-structured elastomeric layer has a lower dielectric constant than that of an unstructured elastomeric layer), which is relatively close to the dielectric constant of vacuum (1.00). In view of this report and further in view of the expression stated above, the resultant dielectric constant of the sensing device does not change significantly when external forces and/or pressure are being applied (Schwartz et al., (2013) Nature Communications 4: 1859).

Importantly, the intermediate micro-structured elastomeric layer in a sensing device of the present invention increases the sensing device's sensitivity, and reduces the response time to any pressure/force applied to the device. This increases the sensing device's reliability (repeatability) in measuring and/or monitoring of forces exerted on an object.

In one embodiment, the micro-structures of the third elastomeric layer may adopt any suitable configuration/profile. For example, suitable configurations may include but are not limited to convex rectangles.

In an embodiment, the rectangular micro-structures may have a dimension in the range of 50×50 μm² to 1000×1000 μm² or preferably about 100×100 μm², and the distance between a pair of adjacent rectangular micro-structures may be in the range of 50 μm to 500 μm or preferably about 100 μm. The thickness of the micro-structured layer may be in the range of 0.8 to 1.6 mm. It will be appreciated that the distance between two adjacent micro-structures would depend on the dimensions of the micro-structures. Specifically, when the micro-structures are smaller in dimensions, the distance would be smaller. Further, the distance between two adjacent micro-structures and dimensions of each micro-structure may vary according to an intended application.

In one embodiment, each of the first or second elastomeric layer may comprise 1 to 100 electrode units, with each electrode unit measuring substantially 1×1 mm².

In an embodiment, the first or second array of electrodes may have a thickness in the range of 0.3 to 1 μm.

In any embodiment, the first and second array of electrodes may be formed/fabricated with one or more suitable materials. For example, suitable materials may include but are not limited to ductile metals, electrically conducting polymers, electrically conductive pastes, electrically conductive gels and electrically conductive inks. In particular, the ductile metals may comprise any one of titanium, copper, silver, gold and platinum. The electrically conducting inks may comprise copper or silver inks.

In particular, an array of gold electrode(s) is noted to demonstrate better stability, reliability, ductility and durability when compared to known elastomeric based electrodes such as the ITO-PET electrodes. Notably, standard MEMS fabrication processes may be used to pattern gold electrodes, thus making mass production of such elastomeric based gold electrodes cost efficient.

In any embodiment, the array of electrodes may comprise any suitable electrode patterns. For example, suitable electrode patterns may include but are not limited to rectangular electrode patterns. It will be appreciated that the electrode pattern may differ depending on the intended application of the elastomeric based electrode.

In one embodiment, the first, second and/or third elastomeric layer may be formed/fabricated with suitable elastomers. Suitable elastomers may include but are not limited to polydimethylsiloxane (PDMS) and polyurethane.

Notably, PDMS possesses the characteristics of good biocompatibility with human tissues, relatively high chemical stability, and transparency. Another important advantage of PDMS derived from its low Young's Modulus is that PDMS thin films are highly conformable (provides an uninterrupted feel of the structures disposed under the sensing device; and may be adaptable to complicated 3-dimensional shapes) and so makes them a useful structural material for the following healthcare, medical and biomedical applications:
bioelectric skin in prosthetics;
biomedical interface (tissues or limb) pressure transducer;
monitoring of pressure points during intra-operative positioning such as facial protection in lateral or prone position;
chronic wound management such as pressure sore monitoring for diabetic food and chronic bedridden patients;
to guide delivery of cricoid pressure within recommended range during airway management to prevent gastric contamination of the lungs;
weight-bearing monitoring such as school bags for school children; and
foot-mapping for foot care applications.

In embodiments of the invention, each of the first or second elastomeric layer may be configured to have a thickness in the range of 10˜50 μm or preferably 20 μm.

It will be appreciated that the number of electrodes provided in an array, dimensions of each electrode, and dimensions of each elastomeric layer may differ according to an intended application.

In one embodiment, the sensing device may detect forces in the range of 0 to 50N.

To this end, the sensing device of the present invention comprises an ultra-thin, compact and simple construct.

In embodiments of the invention, the sensing device may be provided with a first array of interconnects configured to transmit one or more capacitance signals between the electrodes in the first array, and one or more external devices. The sensing device may be provided with a second array of interconnects configured to transmit one or more capacitance signals between the electrodes in the second array, and one or more external devices.

In embodiments of the invention, the interconnects may be copper interconnects.

In one embodiment, the first and second array of electrodes may be configured for pressure mapping. Accordingly, the sensing device in this embodiment may be linked up to a set-up, and display for displaying a map of pressures, using colours, numbers and graphic images of the patient.

In an embodiment, the sensing device may be provided with a scanning program configured for selecting, in sequence, one or more capacitance reading/signal of each pixel of the sensing device. The selected capacitance signal may then be processed, and displayed on the display unit.

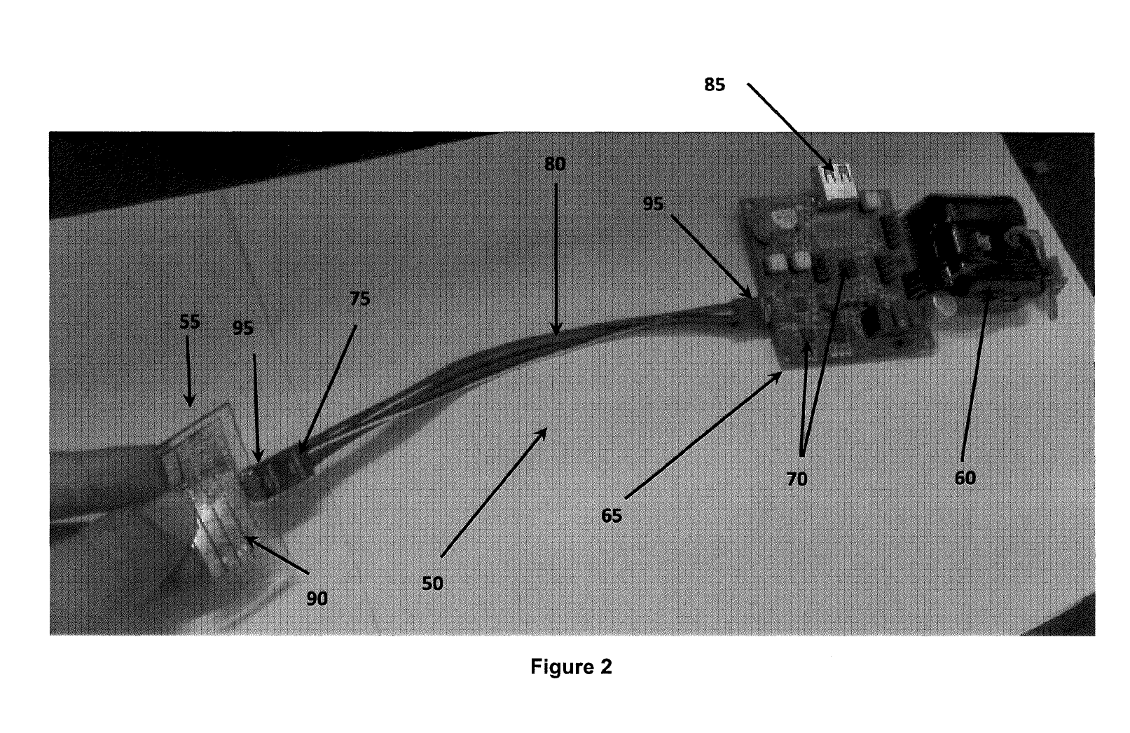

FIG. 2 shows a sensing system 50 according to one embodiment comprising a sensing device 55 according to an embodiment of the invention, a display unit 60, a printed circuit board 65 comprising one or more integrated circuits 70, and a power supply (not shown).

The printed circuit board 65 may be configured to receive one or more signals from the sensing device 55, and to process the signals received to information for real-time display on the display unit 60. In this embodiment, the sensing device 55 connects to the printed circuit board 65 through a double-sided connector 95 comprising multiple wire electrical cables 80.

In an embodiment, the sensing system may comprise one or more multiplexers connected to the first and/or second array of interconnects of the sensing device, said multiplexers configured to select one of several capacitance signals received from the electrodes, and to transmit said selected signal to an external device. Accordingly, the multiplexer 102 functions to select one of several capacitance signals received from the electrodes 90, and to transmit said selected signal to one or more external devices such as, a capacitance-to-voltage converter 75. Accordingly, the capacitance-to-voltage converter 75 converts one or more capacitance signals received from the electrodes 90 to voltage signals for further processing.

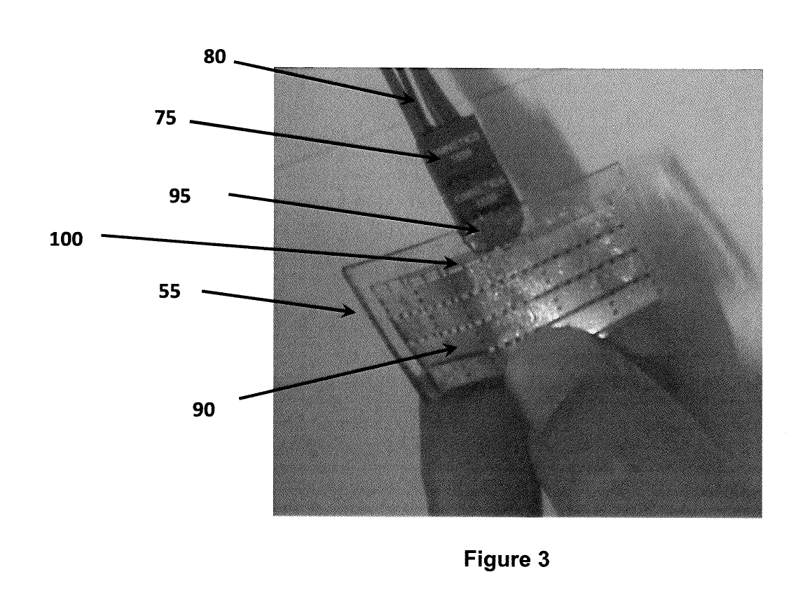

FIG. 3 shows an enlarged figure of the sensing device 55 in FIG. 2. Here, the double-sided connector 95 connects to an array of interconnects 100, which may be connected to the columns and rows of the array of electrodes 90.

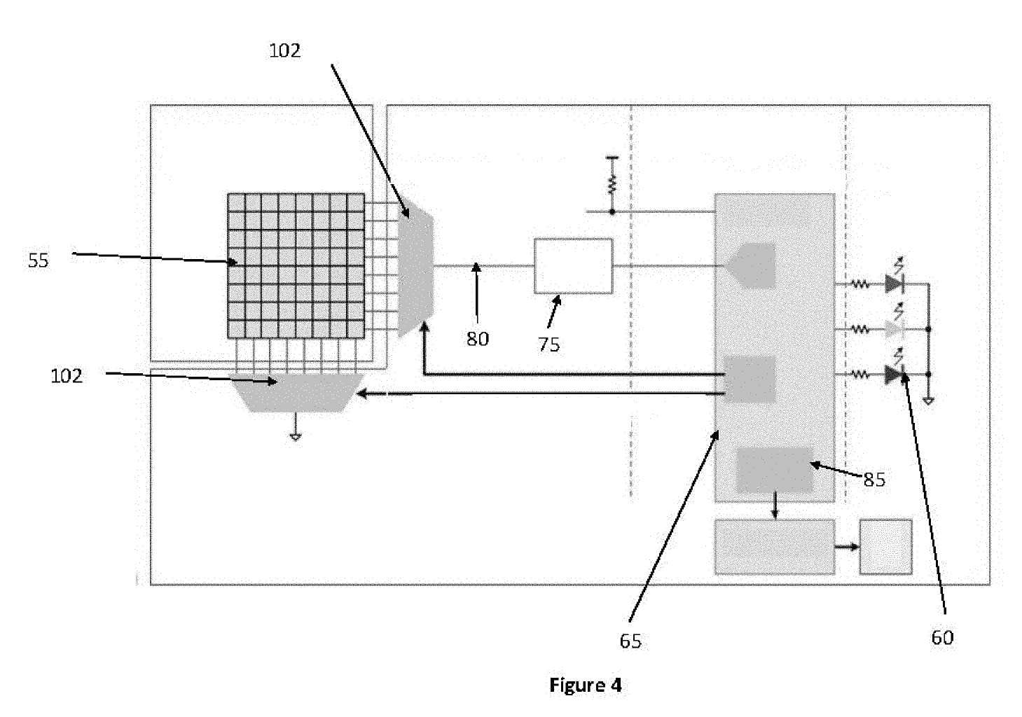

FIG. 4 shows a schematic diagram illustrating the set-up of the sensing system in FIGS. 2 and 3.

In any one embodiment, the printed circuit board may comprise a microprocessor configured to control the reading of the data and/or signals received from one or more external devices, and to convert/process said data and/or signals to information for display on the display unit. Specifically, the data may be converted to information in the form of sound, light and numerical digits to give users of the sensing system real-time feedback of the forces and/or pressure being measured and/or monitored.

In an embodiment, the integrated circuits may be configured to filter and amplify the signals received from the sensing devices and/or one or more external devices, such as a capacitance to voltage converter.

In one embodiment, the printed circuit board 65 may be configured to transmit information to the computer for data analysis and further research.

In embodiments of the invention, the printed circuit board may be provided with a power supply, such as a battery or power cable adaptable to a standard power source, and a switch.

In an embodiment, the system may comprise one or more suitable communication devices for communication of data, information and/or signals between the printed circuit board and one or more external. For example, suitable communication devices may include but are not limited to multiple wire electrical cables, double-sided connectors, Universal Serial Bus (USB) ports and micro USB ports.

In an embodiment, the printed circuit board may comprise one or more of a digital integrated circuit, an analog integrated circuit, a microprocessor, a capacitor, a power supply, a resistor, a logic gate, a memory.

To this end, the sensing device and system of the present invention would automatically calculate the total force applied to the sensing device, based upon the surface area of the sensor on contact with an object (e.g. fingers) exerting the force(s).

### EXAMPLES

### Example 1: Materials and Method for Fabricating the Sensing Device

It will be appreciated that for different elastomer based electrodes, a different curing agent, a different prepolymer, and a different fabrication method may be used accordingly.

The detailed fabrication process for the first and/or second elastomeric (PDMS) based layer can be found in (Schwartz et al., (2013) Nature Communications 4: 1859).

Copper is deposited on the first and/or second elastomeric (PDMS) layer, separately, by using an electron beam evaporator (Zhao et. al., (2014) Journal of Crystal Growth 387; 117-123; and Sun et al., (2012) IEEE Trans Biomed Eng. 59(2):390-9)]. During the evaporation process, a steel shadow mask is placed on one surface of the PDMS layer to pattern the electrodes (copper).

A further elastomeric layer (PDMS) may be formed on the patterned copper electrodes so as to encapsulate said array of copper electrodes (Schwartz et al., (2013) Nature Communications 4: 1859).

The micro-structured/structured elastomeric (PMDS) layer intermediate the first and second elastomeric layer may be formed by molding topology. The molding process may be conducted by using a master mold (e.g. SU-8 master) containing the reverse of the desired features of the micro-structure arrays. The master mold may be designed and obtained by wet-etching copper plate or stainless steel plate, and is commercially available. Also, the mold may be easily fabricated in a laboratory setting.

The elastomeric (PDMS) structured layers may be fabricated by the soft lithographic process, which is briefly described as follows: PDMS prepolymer and curing agent (Sylgard 184A and 184B, Dow Corning) are mixed at a 10:1 ratio. After stirring thoroughly and degassing in a vacuum chamber, the prepared PDMS mixture is poured onto a patterned SU-8 master (GM 1070, Gersteltec Sarl). The PDMS mixture is cured at 90° C. for 60 min. The cured structured PDMS layer is then peeled from the SU-8 master.

It will be appreciated that each of the first, second and micro-structured elastomeric layers may be fabricated separately, laminated in sequence, and then bonded together using suitable adhesives. For example, biocompatible adhesives such as silicone may be used for bonding the elastomeric layers of the sensing device for used in the area of healthcare and medicine. Alternatively, the elastomeric layers may be permanently bonded to one another by exposure to ultraviolet radiation.

To this end, the sensing device of the present invention may be customized according to a specific application, and fabricated using the afore-described methods.

The low-cost methods of fabrication of the present invention make mass-production of the sensing devices on a commercial level cost-efficient. Further, the cost savings derived may allow end-users an option to dispose the sensing device after one use.

It will be appreciated that re-usable instruments come with the ongoing cost of cleaning and sterilizing. Staff time, equipment maintenance and utility consumption are just some of the costs associated with decontamination and sterilization. Re-usable equipment must be cleaned as soon as possible, so daily or weekly collection and delivery services need to be arranged, adding to costs and the environmental impact when considering the energy, chemicals and detergents used in the process. In comparison, single-use instruments can be disposed of with other clinical waste and in the case of metal/allow containing instruments can be recycled.

Further, disposable instruments are also much more practical for visiting doctors and nurses in that they do not need to be stored and taken back to a medical facility for sterilization processing but can instead be safely disposed off immediately.

Notably, the cost-effective benefit, and disposable option of the sensing device of the present invention can bring about further convenience, and safety to the end-users.

### Example 2: Materials and Method for Preparing the Sensing System

The afore-described printed circuit board, communication devices (multiple wire cables, double clip connectors, USB ports and micro USB ports), display, digital integrated circuit, analog integrated circuit, microprocessor, capacitor, power supply, resistor, logic gates, memory, for FIGS. 2 to 5 are commercially available.

### Example 3: Sensing System for Cricoid Force/Pressure Application

The application of cricoid force, sometimes called Sellick's manoeuvre, is an effective approach to prevent regurgitation of gastric contents when correctly applied. However, the force applied by nurses/doctors may be inconsistent, or may vary from the recommended/effective range of pressure required for preventing gastric aspiration. In this regard, Sellick's manoeuvre would be ineffective in preventing gastric aspiration if an inadequate force is applied. In some instances, an excessive amount of force applied may cause harm to the patients.

Reported incidence of lung contamination from gastric contents during anaesthesia is as high as 1 in 2 000 with 1 in 35 000 resulting in significant complications. The incidence of lung contamination from gastric contents is higher for emergency cases (1 in 900), and obstetric patients during Caesarean Section (1 in 900 to 1 in 1500).

Further, the incidence of aspiration has been reported to be 1-20% among patients requiring emergency airway management and 38% in patients intubated in pre-hospital setting.

Cricoid force is the application of force/pressure to the cricoid cartilage of the neck during emergency procedures such as endotracheal intubation.

Recommended guidelines suggest that a force of 10 N should be applied while a patient is awake, while a force of 30N should be applied when the patient has loss his consciousness. The maximum force for unconscious patients should however be less than 44 N. A cricoid force beyond 44N (e.g. 45 N) has been shown to increase the incidence of airway obstruction when compared to a cricoid force of 30 N. On the other hand, the application of too little/insufficient force may lead to regurgitation of gastric contents into the oropharynx, and lead to pulmonary aspiration.

Existing devices for cricoid pressure monitoring and/or application are bulky. The use of such devices is often limited to research purposes. The large footprint of existing devices interferes with airway management by healthcare professionals. Further, such devices fail to provide an uninterrupted feel of the structures disposed (e.g. anatomical structures dispose beneath the device) underneath the device, and so interfere to the effectiveness of the technique used in cricoid pressure application. Further still, such devices fail to adapt to complicated 3-dimensional shapes.

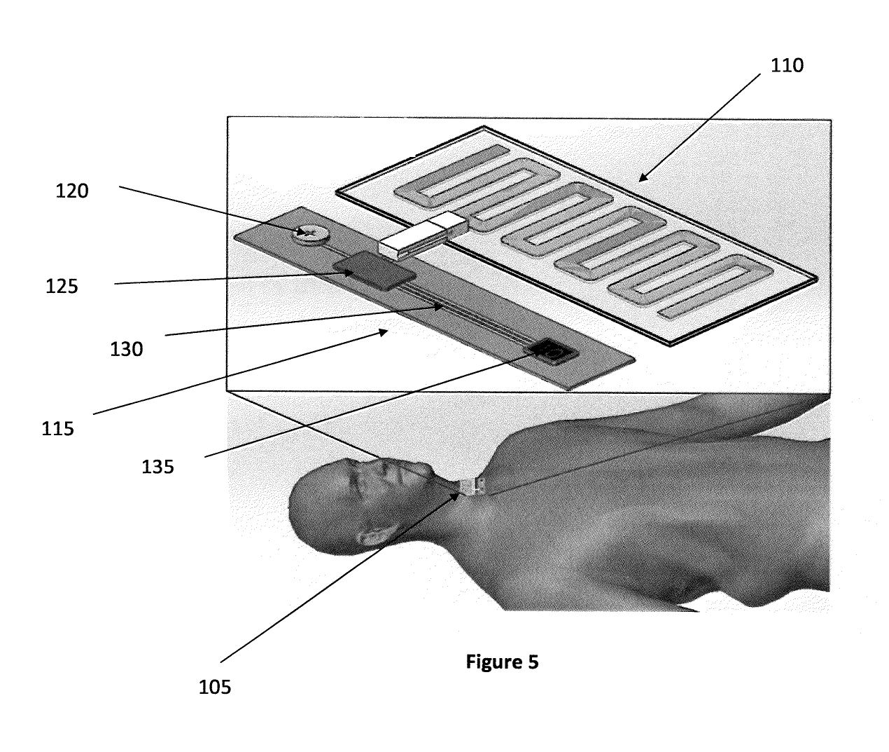

FIG. 5 shows a sensing system 105 according to an embodiment incorporating a sensing device 110 connected to a display circuit 115. The sensing system 105 may be used to guide a user (e.g. nurse or doctor) in the delivery of cricoid pressure/force.

In one embodiment, the display circuit 115 may include a battery 120, a display 125, interconnects 130 and integrated circuits 135.

In embodiments of the invention, the display circuit 115 is commercially available, and may comprise electrical components similar to that as fore-described for the printed circuit board of FIGS. 2 to 4, and hence not repeated for brevity.

In one embodiment, the sensing device 110 may comprise an elastomeric and electrode arrangement similar to that as afore-described for the sensing device of FIGS. 2 to 4, and hence not repeated for brevity.

Relative to known devices, a sensing device and system of the present invention is advantageously thin and compact, and so avoids interfering with the other clinical/surgical procedures. Importantly, the sensing device and system ensures repeatability, and provides a real-time assessment and feedback of the force applied by the clinician.

The pressure mapping function of the present invention makes it suitable for force detection regardless of whether the two or three-finger technique is used. Each pixel of the sensor may be pre-calibrated so as to establish a relationship between the pressure applied to each pixel of the sensor, and the digital output signal. Calibration may be conducted by applying a known pressure. To this end, the pressure distribution on the sensing device on application of an external pressure would be mapped.

Accordingly, the mechanism to convert pressure to force is to multiply the measured pressure distribution by the area of the sensing electrodes (i.e. area of the electrodes on contact when the force(s)/pressure(s) is applied).

### Example 4: Prototype

A sensing device and system prototype has been developed based on the afore-described principle of capacitance variation triggered by external forces/pressure. Specifically, the sensing device comprises an elastomeric arrangement, and circuit configuration similar to that as afore-described for the sensing device and system of FIGS. 2 to 4, and hence not repeated for brevity.

Uniform force was applied to the sensing device, and observations were noted. Accordingly, the capacitance between the two arrays of electrode increases with the force applied. Further, it was observed that the voltage increase took place in the order of milliseconds, and that the sensor shows no hysteresis under repeated use. Further still, the sensing device is capable of detecting a minimum force of 1N or greater within the recommended clinical force range for cricoid force application (approximately 30-44 N).

### DISCUSSION

As seen from the discussion and results noted in Example 4, the sensing device and system of the present invention is wearable, flexible, thin and compact. Importantly, the sensing device and system accurately detects the force applied on the sensing device.

1. A sensing device comprising:
a first array of electrodes encapsulated in a first elastomeric layer;
a second array of electrodes encapsulated in a second elastomeric layer;
a third elastomeric layer intermediate the first and second elastomeric layer and comprising an array of micro-structures,
wherein said electrodes and elastomeric layers are configured such that a displacement of said micro-structures, in response to one or more forces and/or pressures applied to said device, causes a capacitance of said device to vary as a function of said forces and/or pressure applied.

2. A sensing device according to claim 1, wherein the capacitance is inversely proportional to a distance between the first and second array of electrodes.

3. A sensing device according to claim 1, wherein the third elastomeric layer comprises an elastic resistance lower than an elastic resistance of the first or second elastomeric layer.

4. A sensing device according to claim 1, wherein the third elastomeric layer comprises a dielectric constant lower than a dielectric constant of the first or second elastomeric layer.

5. A sensing device according to claim 1, wherein said device further comprises a first array of interconnects configured to transmit one or more capacitance signals between the electrodes in the first array, and one or more external devices.

6. A sensing device according to claim 1, wherein said device further comprises a second array of interconnects configured to transmit one or more capacitance signals between the electrodes in the second array, and one or more external devices.

7. A sensing device according to claim 1, wherein the first, second, and/or third elastomeric layer comprise polydimethylsiloxane (PDMS) or polyurethane.

8. A sensing device according to claim 1, wherein the first and/or second array of electrodes comprises a material selected from the group comprising a ductile metal, an electrically conducting polymer, an electrically conductive paste, an electrically conductive gel and an electrically conductive ink.

9. A sensing device according to claim 8, wherein the ductile metal is selected from the group comprising: titanium, copper, silver, gold and platinum.

10. A sensing system comprising:
a display unit;
a power supply;
one or more sensing devices according to claim 1; and
a printed circuit board comprising one or more integrated circuits configured to receive one or more signals from said sensing devices, and to process said signals received to information for real-time display on the display unit.

11. The sensing system according to claim 10, wherein said system comprises one or more multiplexers connected to the first and/or second array of interconnects, said multiplexers configured to select one of several capacitance signals received from the electrodes, and to transmit said selected signal to an external device.

12. The sensing system according to claim 10, wherein the system further comprises a converter for converting one or more capacitance signals received from the multiplexers to voltage signals for further processing.

13. The sensing system according to claim 10, wherein the printed circuit board comprises one or more of a digital integrated circuit, an analog integrated circuit, a microprocessor, a capacitor, a resistor, a logic gate and a memory.

14. A method of fabricating a sensing device comprising the steps of:
providing a first layer of electrodes encapsulated in a first elastomeric layer;
providing a second layer of electrodes encapsulated in a second elastomeric layer;
providing a third layer elastomeric layer comprising an array of micro-structures;
arranging said layers such that the third layer is intermediate the first and second layers, and a displacement of said micro-structures, in response to one or more forces and/or pressures applied to said device, causes a capacitance of said device to vary as a function of the forces and/or pressures applied.

15. A method according to claim 14, comprising a step after said arranging step, of bonding said layers together with adhesives.

16. A method according to claim 14, comprising a step after said arranging step, exposing the first, second and third elastomeric layers to ultraviolet radiation for bonding said layers together.

17. A method according to claim 14, comprising a step of forming the first, second and/or third layers with PDMS or polyurethane.

18. A method according to claim 14, comprising a step of forming the first and/or second arrays of electrode with a material selected from the group comprising a ductile metal, an electrically conducting polymer, an electrically conductive paste, an electrically conductive gel and an electrically conductive inks.

19. A method according to claim 18, wherein the ductile metal is selected from the group comprising: titanium, copper, silver, gold and platinum.

20. A method according to claim 14, comprising a step of forming the third elastomeric layer by soft lithography.
